(19) United States
(12) Patent Application Publication
(10) Pub. No.: US 2011/0186887 A1
(43) Pub. Date: Aug. 4, 2011

(54) Reflection Mode Wavelength Conversion Material for Optical Devices Using Non-Polar or Semipolar Gallium Containing Materials

(75) Inventors: Troy Anthony Trottier, Goleta, CA (US); Michael Ragan Krames, Goleta, CA (US); Rajat Sharma, Goleta, CA (US); Frank Tin Chung Shum, Goleta, CA (US)

(73) Assignee: Soraa, Inc., Goleta, CA (US)

(21) Appl. No.: 12/887,207

(22) Filed: Sep. 21, 2010

Related U.S. Application Data
(60) Provisional application No. 61/244,443, filed on Sep. 21, 2009.

(51) Int. Cl. H01L 33/50

(52) U.S. Cl. 257/98; 257/E33.061

(57) ABSTRACT

An optical device includes an LED overlying a portion of a surface region of a substrate member and a wavelength conversion material within a vicinity of the LED. The device also includes a wavelength selective surface configured to block direct emission of the LED and configured to transmit selected wavelengths of reflected emission caused by an interaction with the wavelength conversion material.

### CROSS-REFERENCE TO RELATED APPLICATION

This application claims priority from U.S. Patent Application Ser. No. 61/244,443, entitled “Reflection Mode Wavelength Conversion Material for Optical Devices Using Non-Polar or Semipolar Gallium Containing Materials,” filed Sep. 21, 2009, the entirety of which is hereby incorporated by reference.

### BACKGROUND OF THE INVENTION

The present invention relates generally to lighting techniques and more particularly to techniques for transmitting electromagnetic radiation from LED devices, such as ultra-violet, violet, blue, blue and yellow, or blue and green, fabricated on bulk semipolar or nonpolar materials with use of entities such as phosphors, which emit light in a reflection mode. In other embodiments, the starting materials can include polar gallium nitride containing materials, and others. Merely by way of example, the invention can be applied to applications such as white lighting, multi-colored lighting, general illumination, decorative lighting, automotive and aircraft lamps, street lights, lighting for plant growth, indicator lights, lighting for flat panel displays, other optoelectronic devices, and the like.

In the late 1800's, Thomas Edison invented the light bulb. The conventional light bulb, commonly called the “Edison bulb,” has been used for over one hundred years. The conventional light bulb uses a tungsten filament enclosed in a glass bulb sealed in a base, which is screwed into a socket. The socket is coupled to an AC or DC power source. The conventional light bulb can be found commonly in houses, buildings, and outdoor lightings, and other areas requiring light. Unfortunately, the conventional light bulb dissipates more than 90% of the energy used as thermal energy. Additionally, the conventional light bulb routinely fails often due to thermal expansion and contraction of the filament element.

Fluorescent lighting overcomes some of the drawbacks of the conventional light bulb. Fluorescent lighting uses an optically clear tube structure filled with a halogen gas and mercury. A pair of electrodes in the halogen gas are coupled to an alternating power source through a ballast. Once the gas has been excited, it discharges to emit light. Typically, the optically clear tube is coated with phosphors, which are excited by the light. Many building structures use fluorescent lighting and, more recently, fluorescent lighting has been fitted onto a base structure, which couples into a standard socket.

Solid state lighting techniques have also been used. Solid state lighting relies upon semiconductor materials to produce light emitting diodes, commonly called LEDs. At first, red LEDs were demonstrated and introduced into commerce. Red LEDs use Aluminum Indium Gallium Phosphide or AlInGaP semiconductor materials. Most recently, Shuji Nakamura pioneered the use of InGaN materials to produce LEDs emitting light in the blue color range for blue LEDs. The blue colored LEDs led to innovations such as solid state white lighting, the blue laser diode, which in turn enabled the Blu-Ray™ (trademark of the Blu-Ray Disc Association) DVD player, and other developments. Other colored LEDs have also been proposed.

High intensity UV, blue, and green LEDs based on GaN have been proposed and even demonstrated with some success. Efficiencies have typically been highest in the UV-violet, dropping off as the emission wavelength increases to blue or green. Unfortunately, achieving high intensity, high-efficiency GaN-based green LEDs has been particularly problematic. The performance of optoelectronic devices fabricated on conventional c-plane GaN suffer from strong internal polarization fields, which spatially separate the electron and hole wave functions and lead to poor radiative recombination efficiency. Since this phenomenon becomes more pronounced in InGaN layers with increased indium content for increased wavelength emission, extending the performance of UV or blue GaN-based LEDs to the blue-green or green regime has been difficult. Furthermore, since increased indium content films often require reduced growth temperature, the crystal quality of the InGaN films is degraded. The difficulty of achieving a high intensity green LED has lead scientists and engineers to the term “green gap” to describe the unavailability of such green LED. In addition, the light emission efficiency of typical GaN-based LEDs drops off significantly at higher current densities, as are required for general illumination applications, a phenomenon known as “roll-over.” Other limitations with blue LEDs using c-plane GaN exist. These limitations include poor yields, low efficiencies, and reliability issues. Although highly successful, solid state lighting techniques must be improved for full exploitation of their potential. From the above, it is seen that techniques for improving optical devices is highly desired.

### BRIEF SUMMARY OF THE INVENTION

The present invention relates generally to lighting techniques and more particularly to techniques for transmitting electromagnetic radiation from LED devices, such as ultra-violet, violet, blue, blue and yellow, or blue and green, fabricated on bulk semipolar or nonpolar materials with use of entities such as phosphors, which emit light in a reflection mode. In other embodiments, the starting materials can include polar gallium nitride containing materials, and others. Merely by way of example, the invention can be applied to applications such as white lighting, multi-colored lighting, general illumination, decorative lighting, automotive and aircraft lamps, street lights, lighting for plant growth, indicator lights, lighting for flat panel displays, other optoelectronic devices, and the like.

In a specific embodiment, the present invention provides an optical device having a surface region. In a specific embodiment, the substrate is made of a suitable material such a metal, including, but not limited to, Alloy 42, copper, dielectrics, plastics, or others. In a specific embodiment, the substrate is generally from a lead frame member such as a metal alloy. The device also has at least one LED overlying the surface region and at least one exposed portion of the surface region. The device has a wavelength conversion material disposed overlying the at least one exposed portion according to a specific embodiment. The device also has a wavelength selective surface configured to block substantially direct emission of the at least one LED and configured to transmit one or more selected wavelengths of reflected emission caused by an interaction with the wavelength conversion material. In a preferred embodiment, the wavelength selective surface is a transparent material that have filtering properties, but can be others. In a preferred embodiment, the wavelength selective surface is a transparent material such as distributed Bragg Reflector (DBR) stack, a diffraction grating, a particle layer tuned to scatter selective wavelengths, a photonic crystal structure, a nanoparticle layer tuned for plasmon resonance enhancement at certain wavelengths, a dichroic filter, but can be others.

In an alternative specific embodiment, the present invention provides an optical device. The optical device includes at least one LED configured overlying one or more portions of a surface region of a substrate member and a wavelength conversion material within a vicinity of the at least one LED according to a specific embodiment. The device also has a wavelength selective surface configured to block direct emission of the at least one LED and configured to transmit one or more selected wavelengths of reflected emission caused by an interaction with the wavelength conversion material.

In an alternative specific embodiment, the present invention provides a method for providing electromagnetic radiation. The method comprises subjecting one or more wavelength conversion materials using electromagnetic radiation having a reflected characteristic and derived from one or more optoelectronic devices. In a specific embodiment, the electromagnetic radiation is substantially within a first wavelength range. In a preferred embodiment, the method also emits electromagnetic radiation at a second wavelength range from an interaction of the electromagnetic radiation having the reflected characteristic and one or more portions of the wavelength conversion material.

In a specific embodiment, the present invention provides a method for providing electromagnetic radiation. The method includes emitting electromagnetic radiation having a second wavelength range in a second direction according to a specific embodiment. The electromagnetic radiation is derived from one or more interactions between electromagnetic radiation having a first wavelength range in a first direction with one or more portions of a wavelength conversion material. The first direction is different from at least 90 Degrees from the second direction.

Moreover, the present invention provides an alternative optical device. The optical device has a substrate member comprising a surface region and at least one LED configured overlying one or more first portions of the surface region. In a specific embodiment, the at least one LED has LED surface regions. In a specific embodiment, the device also has one or more second portions of the surface region. The device has a wavelength conversion material disposed overlying one or more of the second portions and is configured to expose the LED surface regions.

In still a further embodiment, the present invention provides an optical device, e.g., LED. The optical device has a substrate member comprising a surface region according to a specific embodiment. The device has at least one LED configured overlying one or more first portions of the surface region. In a specific embodiment, the at least one LED has LED surface region(s) that is characterized by a first height from the surface region. In a specific embodiment, one or more second portions of the surface region is included. The optical device also has a wavelength conversion material having one or more portions disposed overlying one or more of the second portions and is configured to have an upper surface having a second height from the surface region. The second height is about the same or less than the first height.

In a yet an alternative embodiment, the present invention provides an optical device, e.g., LED. The device has a substrate member comprising a surface region in a specific embodiment. At least one LED is configured overlying one or more portions of the surface region according to a specific embodiment. The at least one LED has LED surface region(s) and that is characterized by a first height from a reference region. In a specific embodiment, the device has a wavelength conversion material (e.g., phosphor) configured to have an upper surface having a second height from the reference region. In a preferred embodiment, the second height is about less than the first height.

In one or more embodiments, the wavelength conversion material comprises a thickness of material having suitable characteristics. In a specific embodiment, the wavelength conversion material is within about three hundred microns of a thermal sink. In a specific embodiment, the thermal sink comprises a surface region and has a thermal conductivity of greater than about 15 Watt/m-Kelvin, greater than about 100 Watt/m-Kelvin, greater than about 200 Watt/m-Kelvin, greater than about 300 Watt/m-Kelvin, and others. In a specific embodiment, the wavelength conversion material is characterized by an average particle-to-particle distance of about less than about 2 times the average particle size of the wavelength conversion material, is characterized by an average particle-to-particle distance of about less than about 3 times the average particle size of the wavelength conversion material, is characterized by an average particle-to-particle distance of about less than about 5 times the average particle size of the wavelength conversion material, or other dimensions. In a more preferred embodiment, the wavelength conversion material is a filter device. In a preferred embodiment, the wavelength selective surface is a transparent material such as distributed Bragg Reflector (DBR) stack, a diffraction grating, a particle layer tuned to scatter selective wavelengths, a photonic crystal structure, a nanoparticle layer tuned for plasmon resonance enhancement at certain wavelengths, a dichroic filter, but can be others.

One or more benefits may be achieved using one or more of the specific embodiments. As an example, the present device and method provides for an improved lighting technique with improved efficiencies. In other embodiments, the present method and resulting structure are easier to implement using conventional technologies. In a specific embodiment, a blue LED device is capable of emitting electromagnetic radiation at a wavelength range from about 450 nanometers to about 495 nanometers and the yellow-green LED device is capable of emitting electromagnetic radiation at a wavelength range from about 495 nanometers to about 590 nanometers, although there can also be some variations. Depending upon the embodiment, one or more of these benefits can be achieved. These and other benefits are further described throughout the present specification and more particularly below.

A further understanding of the nature and advantages of the present invention may be realized by reference to the latter portions of the specification and attached drawings.

### BRIEF DESCRIPTION OF THE DRAWINGS

FIG. 1 is a simplified diagram of packaged light emitting devices using a flat carrier and cut carrier according to embodiments of the present invention;

FIG. 1A is an example of an electron/hole wave functions according to an embodiment of the present invention;

FIGS. 2 through 12 are simplified diagrams of alternative packaged light emitting devices using one or more reflection mode configurations according to embodiments of the present invention.

### DETAILED DESCRIPTION OF THE INVENTION

According to the present invention, techniques generally for lighting are provided. More specifically, embodiments of the invention include techniques for transmitting electromagnetic radiation from at least one LED, such as ultra-violet, violet, blue, blue and yellow, or blue and green, fabricated on bulk semipolar or nonpolar materials with use of entities such as phosphors, which emit light in a reflection mode. In other embodiments, the starting materials can include polar gallium nitride containing materials, and others. Merely by way of example, the invention can be applied to applications such as white lighting, multi-colored lighting, general illumination, decorative lighting, automotive and aircraft lamps, street lights, lighting for plant growth, indicator lights, lighting for flat panel displays, other optoelectronic devices, and the like.

We have discovered that recent breakthroughs in the field of GaN-based optoelectronics have demonstrated the great potential of devices fabricated on bulk nonpolar and semipolar GaN substrates. The lack of strong polarization induced electric fields that plague conventional devices on c-plane GaN leads to a greatly enhanced radiative recombination efficiency in the light emitting InGaN layers. Furthermore, the nature of the electronic band structure and the anisotropic in-plane strain leads to highly polarized light emission, which will offer several advantages in applications such as display backlighting.

Of particular importance to the field of lighting is the progress of light emitting diodes (LED) fabricated on nonpolar and semipolar GaN substrates. Such devices making use of InGaN light emitting layers have exhibited record output powers at extended operation wavelengths into the violet region (390-430 nm), the blue region (430-490 nm), the green region (490-560 nm), and the yellow region (560-600 nm). For example, a violet LED, with a peak emission wavelength of 402 nm, was recently fabricated on an m-plane (1-100) GaN substrate and demonstrated greater than 45% external quantum efficiency, despite having no light extraction enhancement features, and showed excellent performance at high current densities, with minimal roll-over [K.-C. Kim, M. C. Schmidt, H. Sato, F. Wu, N. Fellows, M. Saito, K. Fujito, J. S. Speck, S. Nakamura, and S. P. DenBaars, “Improved electroluminescence on nonpolar m-plane InGaN/GaN quantum well LEDs”, Phys. Stat. Sol. (RRL) 1, No. 3, 125 (2007).]. Similarly, a blue LED, with a peak emission wavelength of 468 nm, exhibited excellent efficiency at high power densities and significantly less roll-over than is typically observed with c-plane LEDs [K. Iso, H. Yamada, H. Hirasawa, N. Fellows, M. Saito, K. Fujito, S. P. DenBaars, J. S. Speck, and S. Nakamura, “High brightness blue InGaN/GaN light emitting diode on nonpolar m-plane bulk GaN substrate”, Japanese Journal of Applied Physics 46, L960 (2007).]. Two promising semipolar orientations are the (10-1-1) and (11-22) planes. These planes are inclined by 62.0 degrees and by 58.4 degrees, respectively, with respect to the c-plane. University of California, Santa Barbara (UCSB) has produced highly efficient LEDs on (10-1-1) GaN with over 65 mW output power at 100 mA for blue-emitting devices [H. Zhong, A. Tyagi, N. Fellows, F. Wu, R. B. Chung, M. Saito, K. Fujito, J. S. Speck, S. P. DenBaars, and S. Nakamura, “High power and high efficiency blue light emitting diode on freestanding semipolar (1011) bulk GaN substrate”, Applied Physics Letters 90, 233504 (2007)] and on (11-22) GaN with over 35 mW output power at 100 mA for blue-green emitting devices [H. Zhong, A. Tyagi, N. N. Fellows, R. B. Chung, M. Saito, K. Fujito, J. S. Speck, S. P. DenBaars, and S. Nakamura, Electronics Lett. 43, 825 (2007)], over 15 mW of power at 100 mA for green-emitting devices [H. Sato, A. Tyagi, H. Zhong, N. Fellows, R. B. Chung, M. Saito, K. Fujito, J. S. Speck, S. P. DenBaars, and S. Nakamura, “High power and high efficiency green light emitting diode on free-standing semipolar (1122) bulk GaN substrate”, Physical Status Solidi—Rapid Research Letters 1, 162 (2007)] and over 15 mW for yellow devices [H. Sato, R. B. Chung, H. Hirasawa, N. Fellows, H. Masui, F. Wu, M. Saito, K. Fujito, J. S. Speck, S. P. DenBaars, and S. Nakamura, “Optical properties of yellow light-emitting diodes grown on semipolar (1122) bulk GaN substrates,” Applied Physics Letters 92, 221110 (2008).]. The UCSB group has shown that the indium incorporation on semipolar (11-22) GaN is comparable to or greater than that of c-plane GaN, which provides further promise for achieving high crystal quality extended wavelength emitting InGaN layers.

With high-performance single-color non-polar and semi-polar LEDs, several types of white light sources are now possible. In one embodiment, a violet non-polar or semi-polar LED is packaged together with at least one phosphor. In a preferred embodiment, the phosphor comprises a blend of three phosphors, emitting in the blue, the green, and the red. In another embodiment, a blue non-polar or semi-polar LED is packaged together with at least one phosphor. In a preferred embodiment, the phosphor comprises a blend of two phosphors, emitting in the green and the red. In still another embodiment, a green or yellow non-polar or semi-polar LED is packaged together with a blue LED and at least one phosphor. In a preferred embodiment, the phosphor emits in the red. In a preferred embodiment, the blue LED constitutes a blue non-polar or semi-polar LED.

A non-polar or semi-polar LED may be fabricated on a bulk gallium nitride substrate. The gallium nitride substrate may be sliced from a boule that was grown by hydride vapor phase epitaxy or ammonothermally, according to methods known in the art. In one specific embodiment, the gallium nitride substrate is fabricated by a combination of hydride vapor phase epitaxy and ammonothermal growth, as disclosed in U.S. Patent Application No. 61/078,704, commonly assigned, and hereby incorporated by reference herein. The boule may be grown in the c-direction, the m-direction, the a-direction, or in a semi-polar direction on a single-crystal seed crystal. Semipolar planes may be designated by (hkil) Miller indices, where i=−(h+k), l is nonzero and at least one of h and k are nonzero. The gallium nitride substrate may be cut, lapped, polished, and chemical-mechanically polished. The gallium nitride substrate orientation may be within ±5 degrees, ±2 degrees, ±1 degree, or ±0.5 degrees of the {1 −1 0 0} m plane, the {1 1 −2 0} a plane, the {1 1 −2 2} plane, the {2 0 −2 ±1} plane, the {1 −1 0 ±1} plane, the {1 −1 0 −±2} plane, or the {1 −1 0 ±3} plane. The gallium nitride substrate may have a dislocation density in the plane of the large-area surface that is less than 10⁶ cm⁻², less than 10⁵ cm⁻², less than 10⁴ cm⁻², or less than 10³ cm⁻². The gallium nitride substrate may have a dislocation density in the c plane that is less than 10⁶ cm⁻², less than 10⁵ cm⁻², less than 10⁴ cm⁻², or less than 10³ cm⁻².

A homoepitaxial non-polar or semi-polar LED is fabricated on the gallium nitride substrate according to methods that are known in the art, for example, following the methods disclosed in U.S. Pat. No. 7,053,413, which is hereby incorporated by reference in its entirety. At least one AlₓIn_{y}Ga_{1-x-y}N layer, where 0≦x≦1, 0≦y≦1, and 0≦x+y≦1, is deposited on the substrate, for example, following the methods disclosed by U.S. Pat. Nos. 7,338,828 and 7,220,324, which are hereby incorporated by reference in their entirety. The at least one AlₓIn_{y}Ga_{1-x-y}N layer may be deposited by metal-organic chemical vapor deposition, by molecular beam epitaxy, by hydride vapor phase epitaxy, or by a combination thereof. In one embodiment, the AlₓIn_{y}Ga_{1-x-y}N layer comprises an active layer that preferentially emits light when an electrical current is passed through it. In one specific embodiment, the active layer comprises a single quantum well, with a thickness between about 0.5 nm and about 40 nm. In a specific embodiment, the active layer comprises a single quantum well with a thickness between about 1 nm and about 5 nm. In other embodiments, the active layer comprises a single quantum well with a thickness between about 5 nm and about 10 nm, between about 10 nm and about 15 nm, between about 15 nm and about 20 nm, between about 20 nm and about 25 nm, between about 25 nm and about 30 nm, between about 30 nm and about 35 nm, or between about 35 nm and about 40 nm. In another set of embodiments, the active layer comprises a multiple quantum well. In still another embodiment, the active region comprises a double heterostructure, with a thickness between about 40 nm and about 500 nm. In one specific embodiment, the active layer comprises an In_{y}Ga_{1-y}N layer, where 0≦y≦1.

In a specific embodiment, the present invention provides novel packages and devices including at least one non-polar or at least one semi-polar homoepitaxial LED is placed on a substrate. In other embodiments, the starting materials can include polar gallium nitride containing materials and others. The present packages and devices are combined with phosphor entities to discharge white light according to a specific embodiment. Further details of the present packages and methods can be found throughout the present specification and more particularly below.

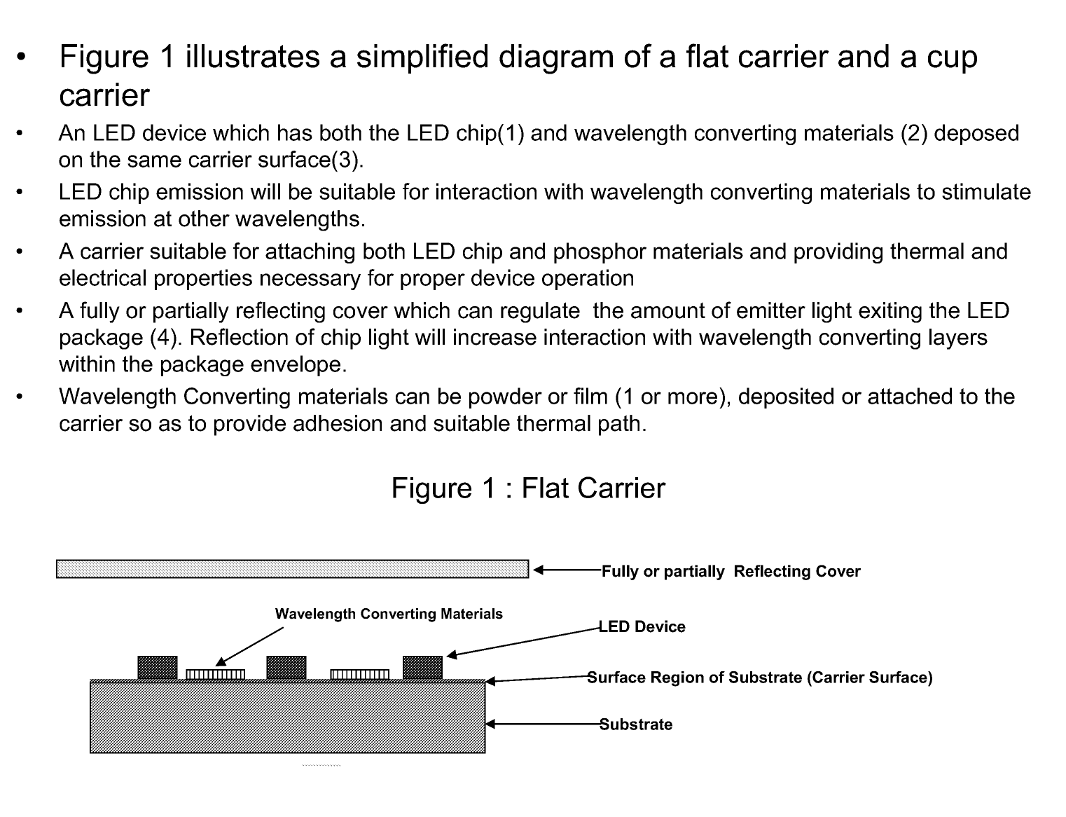

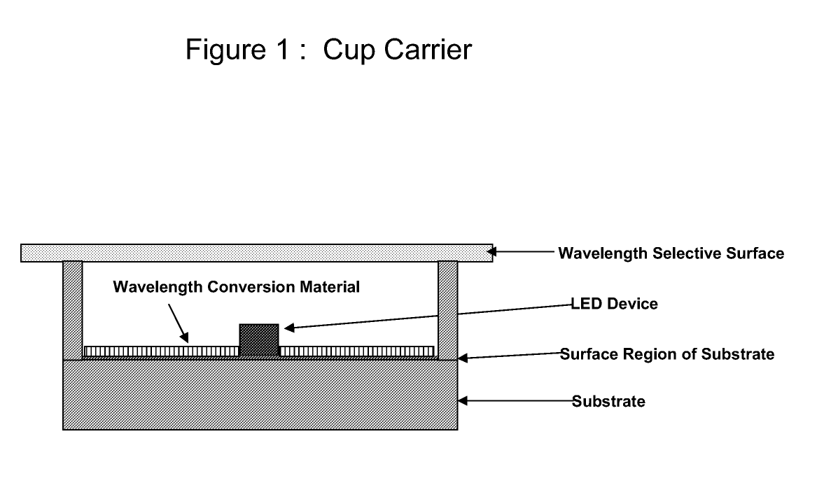

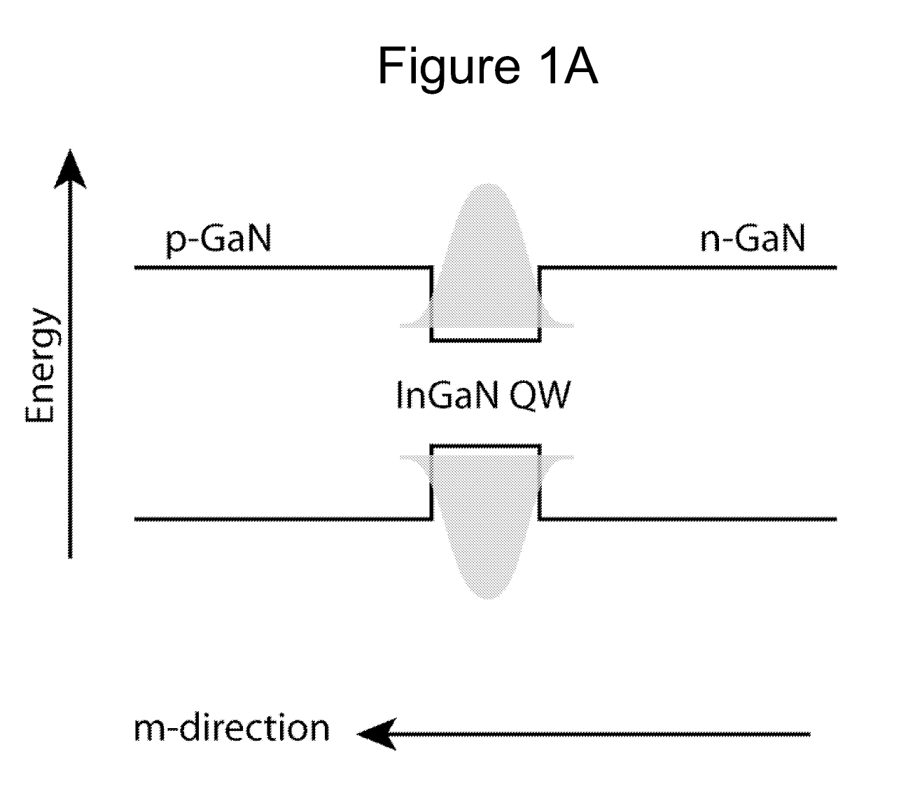

FIG. 1 illustrates simplified diagrams of a flat carrier packaged light emitting device 100 and recessed or cup packaged light emitting device 110 according to embodiments of the present invention. This diagram is merely an illustration and should not unduly limit the scope of the claims herein. One of ordinary skill in the art would recognize other variations, modifications, and alternatives. In a specific embodiment, the present invention provides a packaged light emitting device configured in a flat carrier package 100. As shown, the device has a substrate member comprising a surface region. In a specific embodiment, the substrate is made of a suitable material such a metal including, but not limited to, Alloy 42, copper, and others, among plastics, dielectrics, and the like. In a specific embodiment, the substrate is generally from a lead frame member such as metal alloy, but can be others.

In a specific embodiment, the present substrate, which holds the LED, can come in various shapes, sizes, and configurations. In a specific embodiment, the surface region of the flat carrier is substantially flat, although there may be one or more slight variations the surface region. Alternatively, the surface region is cupped or terraced according to a specific embodiment. In other embodiments, the surface region can also be combinations of the flat and cupped shapes, among others. Additionally, the surface region generally comprises a smooth surface, plating, or coating. Such plating or coating can be gold, silver, platinum, aluminum, or any pure or alloy material, which is suitable for bonding to an overlying semiconductor material, but can be others.

Referring again to FIG. 1, the device has one or more light emitting diode devices overlying the surface region in each of the configurations (1) flat; and (2) cup. At least one of the light emitting diode devices 103 is fabricated on a semipolar or nonpolar GaN containing substrate, but can be other materials, such as polar gallium and nitrogen containing material and others. In a specific embodiment, the device emits polarized electromagnetic radiation 105. As shown, the light emitting device is coupled to a first potential, which is attached to the substrate, and a second potential 109, which is coupled to wire or lead 111 bonded to a light emitting diode.

In a specific embodiment, the device has at least one of the light emitting diode devices comprising a quantum well region. In a specific embodiment, the quantum well region is characterized by an electron wave function and a hole wave function. The electron wave function and the hole wave function are substantially overlapped within a predetermined spatial region of the quantum well region according to a specific embodiment. An example of the electron wave function and the hole wave function is provided by FIG. 1A.

In a preferred embodiment, the one or more light emitting diode device comprises at least a blue LED device. In a specific embodiment, the substantially polarized emission is blue light. The one or more light emitting diode device comprises at least a blue LED device capable of emitting electromagnetic radiation at a range from about 430 nanometers to about 490 nanometers, which is substantially polarized emission being blue light. In a specific embodiment, a {1 −1 0 0} m-plane bulk substrate is provided for the nonpolar blue LED. In another specific embodiment, a {1 0 −1 −1} semi-polar bulk substrate is provided for the semipolar blue LED. The substrate has a flat surface, with a root-mean-square (RMS) roughness of about 0.1 nm, a threading dislocation density less than 5×10⁶ cm⁻², and a carrier concentration of about 1×10¹⁷ cm⁻³. Epitaxial layers are deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth is between about 3000 and about 12000. First, a contact layer of n-type (silicon-doped) GaN is deposited on the substrate, with a thickness of about 5 microns and a doping level of about 2×10¹⁸ cm⁻³. Next, an undoped InGaN/GaN multiple quantum well (MQW) is deposited as the active layer. The MQW superlattice has six periods, comprising alternating layers of 8 nm of InGaN and 37.5 nm of GaN as the barrier layers. Next, a 10 nm undoped AlGaN electron blocking layer is deposited. Finally, a p-type GaN contact layer is deposited, with a thickness of about 200 nm and a hole concentration of about 7×10¹⁷ cm⁻³. Indium tin oxide (ITO) is e-beam evaporated onto the p-type contact layer as the p-type contact and rapid-thermal-annealed. LED mesas, with a size of about 300×300 μm², are formed by photolithography and dry etching using a chlorine-based inductively-coupled plasma (ICP) technique. Ti/Al/Ni/Au is e-beam evaporated onto the exposed n-GaN layer to form the n-type contact, Ti/Au is e-beam evaporated onto a portion of the ITO layer to form a p-contact pad, and the wafer is diced into discrete LED dies. Electrical contacts are formed by conventional wire bonding.

In a specific embodiment of the flat carrier, the present device also has a thickness 115 of one or more entities formed on an exposed portion of the substrate separate and apart from the one or more light emitting diode devices. In a preferred embodiment, the one or more entities are wavelength conversion materials that convert electromagnetic radiation reflected off the wavelength selective material, as shown. In a specific embodiment, the one or more entities are excited by the substantially polarized emission and emit electromagnetic radiation of one or more second wavelengths. In a preferred embodiment, the plurality of entities is capable of emitting substantially yellow light from an interaction with the substantially polarized emission of blue light. In a specific embodiment, the thickness of the plurality of entities, which are phosphor entities, is about five microns and less.

In a specific embodiment, the one or more entities comprises a phosphor or phosphor blend selected from one or more of (Y, Gd, Tb, Sc, Lu, La)₃(Al, Ga, In)₅O₁₂:Ce³⁺, SrGa₂S₄:Eu²⁺, SrS:Eu²⁺, and colloidal quantum dot thin films comprising CdTe, ZnS, ZnSe, ZnTe, CdSe, or CdTe. In other embodiments, the device may include a phosphor capable of emitting substantially red light. Such phosphor is selected from one or more of (Gd,Y,Lu,La)₂O₃:Eu³⁺, Bi³⁺; (Gd,Y,Lu,La)₂O₂S:Eu³⁺, Bi³⁺; (Gd,Y,Lu,La)VO₄:Eu³⁺, Bi³⁺; Y₂(O,S)₃: Eu³⁺; Ca₁₋ₓMo_{1-y}Si_{y}O₄, where 0.05≦x≦0.5, 0≦y≦0.1; (Li,Na,K)₅Eu(W,Mo)O₄; (Ca,Sr)S:Eu²⁺; SrY₂S₄:Eu²⁺; CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgxP₂O₇:Eu²⁺, Mn²⁺; (Y,Lu)₂WO₆:Eu³⁺, Mo⁶⁺; (Ba,Sr,Ca)₃MgxSi₂O₈:Eu²⁺, Mn²⁺, wherein 1<x≦2; (RE_{1-y}Ce_{y})Mg₂₋ₓ,LiₓSi₃₋ₓPₓO₁₂, where RE is at least one of Sc, Lu, Gd, Y, and Tb, 0.0001<x<0.1 and 0.001<y<0.1; (Y, Gd, Lu, La)₂₋ₓ,EuₓW_{1-y}Mo_{y}O₆,where 0.5≦x≦1.0, 0.01≦y≦1.0; (SrCa)₁₋ₓEuₓSi₅N₈, where 0.01≦x≦0.3; SrZnO₂:Sm⁺³; MₘOₙX wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

In one or more embodiments, wavelength conversion materials can be ceramic, thin-film-deposited, or discrete particle phosphors, ceramic or single-crystal semiconductor plate down-conversion materials, organic or inorganic downconverters, nanoparticles, or any other materials which absorb one or more photons of a primary energy and thereby emit one or more photons of a secondary energy (“wavelength conversion”). As an example, the wavelength conversion materials can include, but are not limited to the following:
(Sr,Ca)₁₀(PO₄)6*DB₂O₃:Eu²⁺ (wherein 0<n₁)
(Ba,Sr,Ca)₅(PO₄)₃(Cl,F,Br,OH):Eu²⁺,Mn²⁺
(Ba,Sr,Ca)BPO₅:Eu²⁺,Mn²⁺
Sr₂Si₃O₈*2SrC₁₂:Eu²⁺
(Ca,Sr,Ba)₃MgSi₂O₈:Eu²⁺, Mn²⁺
BaA₁₈O₁₃:Eu²⁺
₂SrO*0.84P₂O₅*0.16B₂O₃:Eu²⁺
(Ba,Sr,Ca)MgAl₁0O₁₇:Eu²⁺,Mn²⁺
(Ba,Sr,Ca)Al₂O₄:Eu²⁺
(Y,Gd,Lu,Sc,La)BO₃:Ce³⁺,Tb³⁺
(Ba,Sr,Ca)₂(Mg,Zn)Si₂O₇:Eu²⁺
(Mg,Ca,Sr, Ba,Zn)₂Si₁_{_{—}}ₓO₄_{_{—}}₂x:Eu²⁺(wherein 0<x=0.2)
(Sr,Ca,Ba)(Al,Ga,m)₂S₄:Eu²⁺
(Lu,Sc,Y,Tb)₂_{_{—}}ᵤ_{_{—}}ᵥCevCa₁₊ᵤLiwMg₂_{_{—}}_{w}Pw(Si,Ge)₃_{_{—}}_{w}01₂_{_{—}}ᵤ/2 where —O.SSû1; 0<v£Q.1; and OSŵO.2
(Ca,Sr)₈(Mg,Zn)(SiO₄)₄C₁₂:Eu²⁺,Mn²⁺
Na₂Gd₂B₂O₇:Ce³⁺,Tb³⁺
(Sr,Ca,Ba,Mg,Zn)₂P₂O₇:Eu²⁺,Mn²⁺
(Gd,Y,Lu,La)₂O₃:Eu³⁺,Bi³⁺
(Gd,Y,Lu,La)₂O₂S:Eu³⁺,Bi^{3 +}
(Gd,Y,Lu,La)_{V}O₄:Eu³⁺,Bi³⁺
(Ca,Sr)S:Eu²⁺,Ce³⁺
(Y,Gd,Tb,La,Sm,Pr,Lu)₃(Sc,Al,Ga)₅_{_{—}}ₙO₁₂_{_{—}}₃/₂n:Ce³⁺ (wherein 0̂0̂0.5)
ZnS:Cu+,Cl˜
ZnS:Cu+,Al³⁺
ZnS:Ag+,Al³⁺
SrY₂S₄:EU²⁺
CaLa₂S₄:Ce³⁺
(Ba,Sr,Ca)MgP₂O₇:Eu2+,Mn²⁺
(Y,Lu)₂WO₆:Eu³⁺,Mo⁶⁺
(Ba,Sr,Ca)nSinNn:Eu²⁺ (wherein 2ₙ₊₄=3n)
Ca₃(SiO₄)Cl₂:Eu²⁺
ZnS:Ag+,Cl˜
(Y,Lu,Gd)₂_{_{—}}ₙCanSi₄N₆₊ₙC₁_{_{—}}ₙ:Ce3+, (wherein OSn̂O.5)
(Lu,Ca,Li,Mg,Y)alpha-SiAlON doped with Eu²⁺ and/or Ce³⁺
(Ca,Sr,Ba)SiO₂N₂:Eu²⁺,Ce³⁺

For purposes of the application, it is understood that when a phosphor has two or more dopant ions (i.e., those ions following the colon in the above phosphors), this is to mean that the phosphor has at least one (but not necessarily all) of those dopant ions within the material. That is, as understood by those skilled in the art, this type of notation means that the phosphor can include any or all of those specified ions as dopants in the formulation.

In a specific embodiment, the one or more light emitting diode device comprises at least a violet LED device capable of emitting electromagnetic radiation at a range from about 380 nanometers to about 440 nanometers and the one or more entities are capable of emitting substantially white light, the substantially polarized emission being violet light. In a specific embodiment, a (1 −1 0 0) m-plane bulk substrate is provided for the nonpolar violet LED. The substrate has a flat surface, with a root-mean-square (RMS) roughness of about 0.1 nm, a threading dislocation density less than 5×10⁶ cm⁻², and a carrier concentration of about 1×10¹⁷ cm⁻³. Epitaxial layers are deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth is between about 3000 and about 12000. First, a contact layer of n-type (silicon-doped) GaN is deposited on the substrate, with a thickness of about 5 microns and a doping level of about 2×10¹⁸ cm⁻³. Next, an undoped InGaN/GaN multiple quantum well (MQW) is deposited as the active layer. The MQW superlattice has six periods, comprising alternating layers of 16 nm of InGaN and 18 nm of GaN as the barrier layers. Next, a 10 nm undoped AlGaN electron blocking layer is deposited. Finally, a p-type GaN contact layer is deposited, with a thickness of about 160 nm and a hole concentration of about 7×10¹⁷ cm⁻³. Indium tin oxide (ITO) is e-beam evaporated onto the p-type contact layer as the p-type contact and rapid-thermal-annealed. LED mesas, with a size of about 300×300 μm2, are formed by photolithography and dry etching. Ti/Al/Ni/Au is e-beam evaporated onto the exposed n-GaN layer to form the n-type contact, Ti/Au is e-beam evaporated onto a portion of the ITO layer to form a contact pad, and the wafer is diced into discrete LED dies. Electrical contacts are formed by conventional wire bonding. Other colored LEDs may also be used or combined according to a specific embodiment.

In a specific embodiment, a (1 1 −2 2} bulk substrate is provided for a semipolar green LED. The substrate has a flat surface, with a root-mean-square (RMS) roughness of about 0.1 nm, a threading dislocation density less than 5×10⁶ cm⁻², and a carrier concentration of about 1×10¹⁷ cm⁻³. Epitaxial layers are deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth between about 3000 and about 12000. First, a contact layer of n-type (silicon-doped) GaN is deposited on the substrate, with a thickness of about 1 micron and a doping level of about 2×10¹⁸ cm⁻³. Next, an InGaN/GaN multiple quantum well (MQW) is deposited as the active layer. The MQW superlattice has six periods, comprising alternating layers of 4 nm of InGaN and 20 nm of Si-doped GaN as the barrier layers and ending with an undoped 16 nm GaN barrier layer and a 10 nm undoped Al_{0.1}5Ga_{0.85}N electron blocking layer. Finally, a p-type GaN contact layer is deposited, with a thickness of about 200 nm and a hole concentration of about 7×10¹⁷ cm⁻³. Indium tin oxide (ITO) is e-beam evaporated onto the p-type contact layer as the p-type contact and rapid-thermal-annealed. LED mesas, with a size of about 200×550 μm², are formed by photolithography and dry etching. Ti/Al/Ni/Au is e-beam evaporated onto the exposed n-GaN layer to form the n-type contact, Ti/Au is e-beam evaporated onto a portion of the ITO layer to form a contact pad, and the wafer is diced into discrete LED dies. Electrical contacts are formed by conventional wire bonding.

In another specific embodiment, a (1 1 −2 2} bulk substrate is provided for a semipolar yellow LED. The substrate has a flat surface, with a root-mean-square (RMS) roughness of about 0.1 nm, a threading dislocation density less than 5×10⁶ cm⁻², and a carrier concentration of about 1×10¹⁷ cm⁻³. Epitaxial layers are deposited on the substrate by metalorganic chemical vapor deposition (MOCVD) at atmospheric pressure. The ratio of the flow rate of the group V precursor (ammonia) to that of the group III precursor (trimethyl gallium, trimethyl indium, trimethyl aluminum) during growth between about 3000 and about 12000. First, a contact layer of n-type (silicon-doped) GaN is deposited on the substrate, with a thickness of about 2 microns and a doping level of about 2×10¹⁸ cm⁻³. Next, a single quantum well (SQW) is deposited as the active layer. The SQW comprises a 3.5 nm InGaN layer and is terminated by an undoped 16 nm GaN barrier layer and a 7 nm undoped Al_{0.15}Ga_{0.85}N electron blocking layer. Finally, a Mg-doped p-type GaN contact layer is deposited, with a thickness of about 200 nm and a hole concentration of about 7×10¹⁷ cm⁻³. Indium tin oxide (ITO) is e-beam evaporated onto the p-type contact layer as the p-type contact and rapid-thermal-annealed. LED mesas, with a size of about 600×450 μm², are formed by photolithography and dry etching. Ti/Al/Ni/Au is e-beam evaporated onto the exposed n-GaN layer to form the n-type contact, Ti/Au is e-beam evaporated onto a portion of the ITO layer to form a contact pad, and the wafer is diced into discrete LED dies. Electrical contacts are formed by conventional wire bonding.

In a specific embodiment, the one or more entities comprise a blend of phosphors capable of emitting substantially blue light, substantially green light, and substantially red light. As an example, the blue emitting phosphor is selected from the group consisting of (Ba,Sr,Ca)₅(PO₄)₃(Cl,F,Br,OH):Eu²⁺, Mn²⁺;Sb³⁺,(Ba,Sr,Ca)MgAl₁₀O₁₇:Eu²⁺, Mn²⁺; (Ba,Sr,Ca)BPO₅:Eu²⁺, Mn²⁺; (Sr,Ca)₁₀(PO₄)₆*nB₂O₃:Eu²⁺; 2SrO*0.84P₂O₅*0.16B₂O₃:Eu²⁺; Sr₂Si₃O₈*2SrCl₂:Eu²⁺; (Ba,Sr,Ca)MgₓP₂O₇:Eu²⁺, Mn²⁺; Sr₄Al₁₄O₂₅:Eu²⁺ (SAE); BaAl₈O₁₃:Eu²⁺; and mixtures thereof. As an example, the green phosphor is selected from the group consisting of (Ba,Sr,Ca)MgAl₁₀O₁₇:Eu²⁺, Mn²⁺ (BAMn); (Ba,Sr,Ca)Al₂O₄:Eu²⁺; (Y,Gd,Lu,Sc,La)BO₃:Ce³⁺,Tb³⁺; Ca₈Mg(SiO₄)₄Cl₂:Eu²⁺, Mn²⁺; (Ba,Sr,Ca)₂SiO₄:Eu²⁺; (Ba,Sr,Ca)₂(Mg,Zn)Si₂O₇:Eu²⁺; (Sr,Ca,Ba)(Al,Ga,In)₂S₄:Eu²⁺; (Y,Gd,Tb,La,Sm,Pr,Lu)₃(Al,Ga)₅O₁₂:Ce³⁺; (Ca,Sr)₈(Mg,Zn)(SiO₄)₄C₁₂:Eu²⁺, Mn²⁺ (CASI); Na₂Gd₂B₂O₇:Ce³⁺, Tb³⁺; (Ba,Sr)₂(Ca,Mg,Zn)B₂O₆:K,Ce,Tb; and mixtures thereof. As an example, the red phosphor is selected from the group consisting of (Gd,Y,Lu,La)₂O₃:Eu³⁺, Bi³⁺; (Gd,Y,Lu,La)₂O₂S:Eu³⁺, Bi³⁺; (Gd,Y,Lu,La)VO₄:Eu³⁺, Bi³⁺; Y₂(O,S)₃: Eu³⁺; Ca₁₋ₓMo_{1-y} SiO₄, where 0.05≦x≦0.5, 0≦y≦0.1; (Li,Na,K)₅Eu(W,Mo)O₄; (Ca,Sr)S:Eu²⁺; SrY₂S₄:Eu²⁺CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgₓP₂O₇:Eu²⁺, Mn²⁺; (Y,Lu)₂WO₆:Eu³⁺, Mo⁶⁺; (Ba,Sr,Ca)₃MgₓSi₂O₈:Eu²⁺, Mn²⁺, wherein 1<x≦2; (RE_{1-y}Ce_{y})Mg₂₋ₓ,LiₓSi₃₋ₓPₓO₁₂, where RE is at least one of Sc, Lu, Gd, Y, and Tb, 0.0001<x<0.1 and 0.001<y<0.1; (Y, Gd, Lu, La)₂₋ₓEuₓW_{1-y}Mo_{y}O₆,where 0.5≦x.≦1.0, 0.01≦y≦1.0; (SrCa)₁₋ₓEuₓSi₅N₈, where 0.01≦x≦0.3; SrZnO₂:Sm⁺³; MₘOₙX, wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

In a specific embodiment, the above has been generally described in terms of one or more entities that may be one or more phosphor materials or phosphor like materials, but it would be recognized that other “energy-converting luminescent materials”, which may include phosphors, semiconductors, semiconductor nanoparticles (“quantum dots”), organic luminescent materials, and the like, and combinations of them, and also be used. In one or more preferred embodiments, the energy converting luminescent materials can generally be a wavelength converting material and/or materials.

In a specific embodiment, the present packaged device having a flat carrier configuration includes an enclosure 117, which includes a flat region that is wavelength selective. The enclosure can be made of a suitable material such as an optically transparent plastic, glass, or other material. As also shown, the enclosure has a suitable shape 119 according to a specific embodiment. The shape can be annular, circular, egg-shaped, trapezoidal, or any combination of these shapes. As shown referring to the cup carrier configuration, the packaged device is provided within a terraced or cup carrier. Depending upon the embodiment, the enclosure with suitable shape and material is configured to facilitate and even optimize transmission of electromagnetic radiation reflected from one or more internal regions of the package of the LED device. In a specific embodiment, the wavelength selective material is a filter device that can be applied as a coating through the surface region of the enclosure. In a preferred embodiment, the wavelength selective surface is a transparent material such as distributed Bragg Reflector (DBR) stack, a diffraction grating, a particle layer tuned to scatter selective wavelengths, a photonic crystal structure, a nanoparticle layer tuned for plasmon resonance enhancement at certain wavelengths, a dichroic filter, but can be others.

In one or more embodiments, the wavelength conversion material comprises a thickness of material having suitable characteristics. In a specific embodiment, the wavelength conversion material is within about three hundred microns of a thermal sink. In a specific embodiment, the thermal sink comprises a surface region and has a thermal conductivity of greater than about 15 Watt/m-Kelvin, greater than about 100 Watt/m-Kelvin, greater than about 200 Watt/m-Kelvin, greater than about 300 Watt/m-Kelvin, and others. In a specific embodiment, the wavelength conversion material is characterized by an average particle-to-particle distance of about less than about 2 times the average particle size of the wavelength conversion material, is characterized by an average particle-to-particle distance of about less than about 3 times the average particle size of the wavelength conversion material, is characterized by an average particle-to-particle distance of about less than about 5 times the average particle size of the wavelength conversion material, or other dimensions. In a more preferred embodiment, the wavelength conversion material is filter device. In a preferred embodiment, the wavelength selective surface is a transparent material such as distributed Bragg Reflector (DBR) stack, a diffraction grating, a particle layer tuned to scatter selective wavelengths, a photonic crystal structure, a nanoparticle layer tuned for plasmon resonance enhancement at certain wavelengths, a dichroic filter, but can be others.

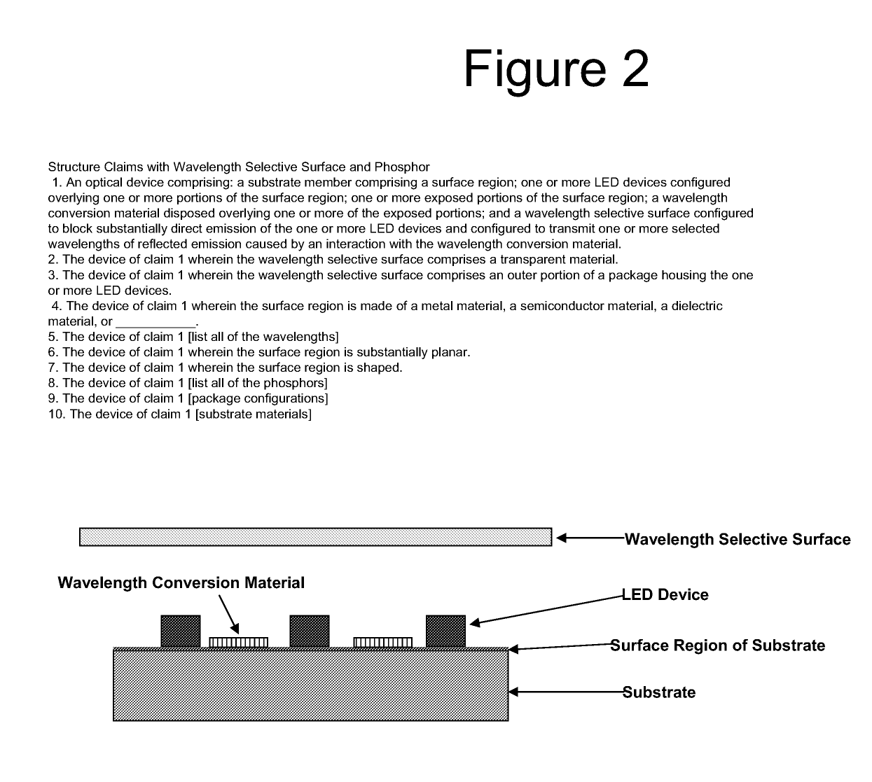

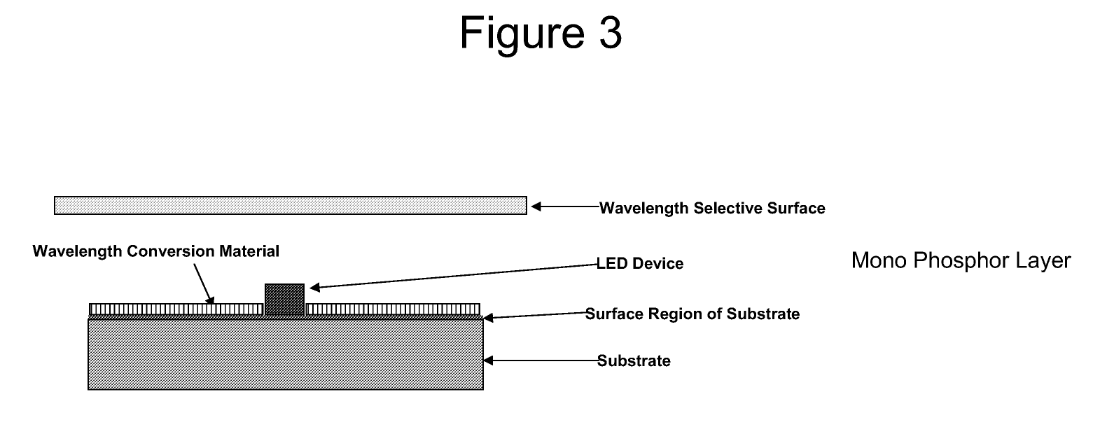

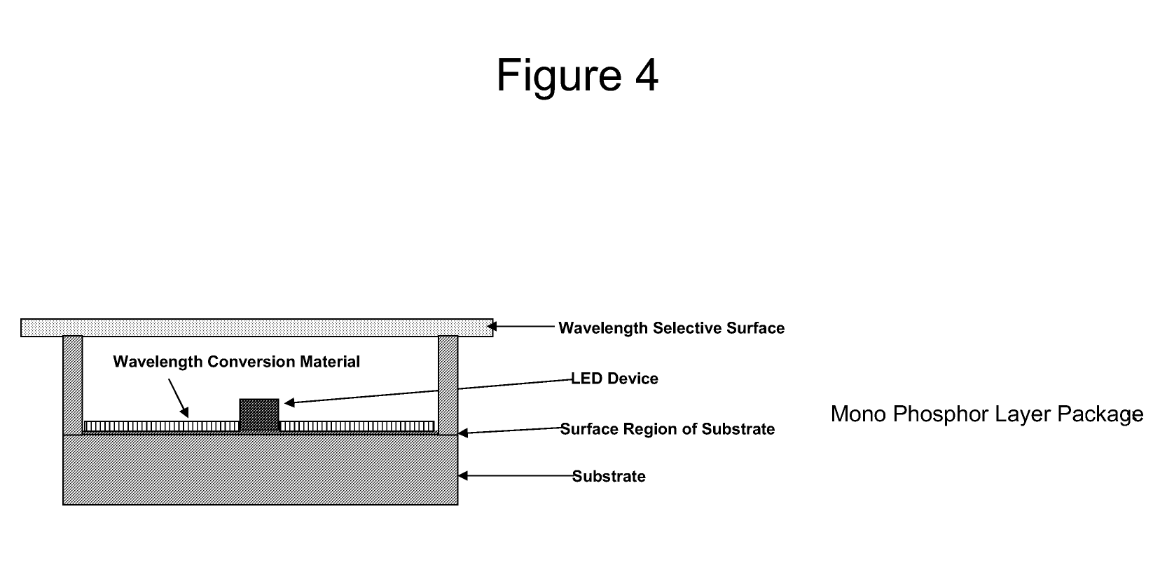

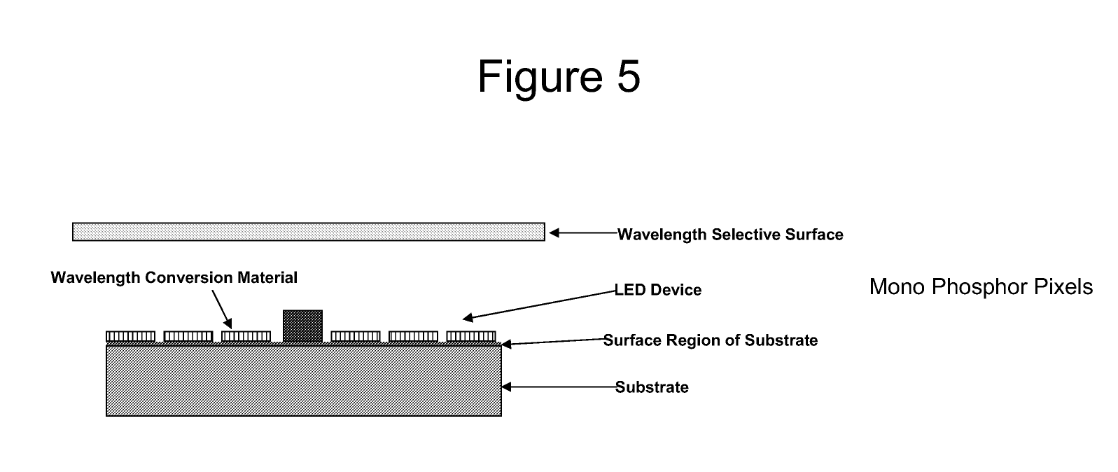

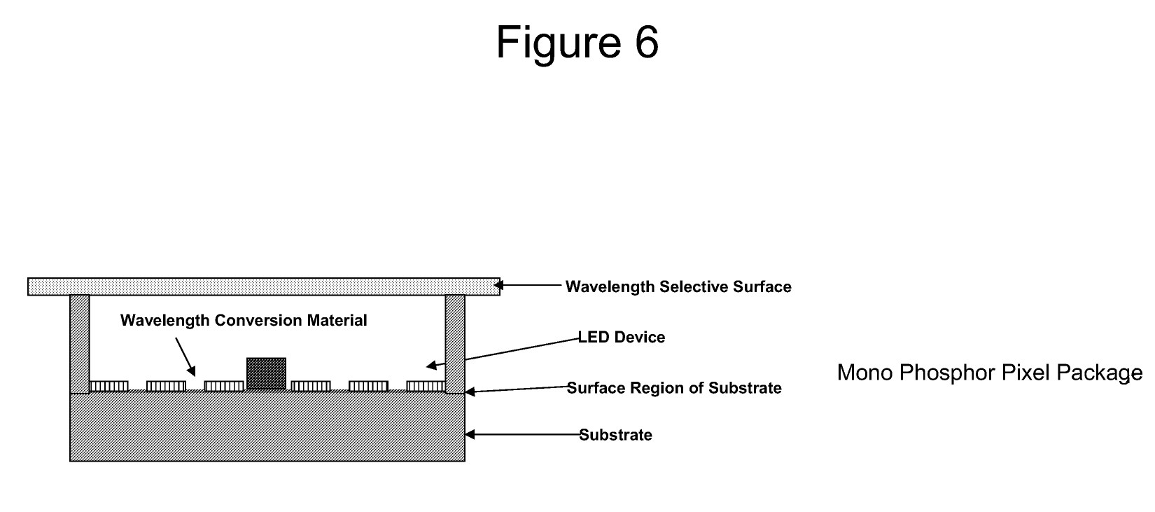

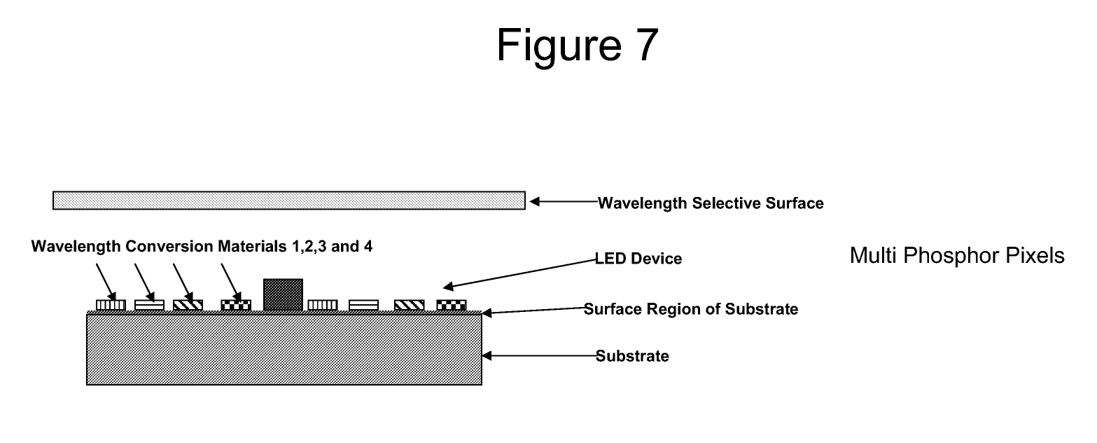

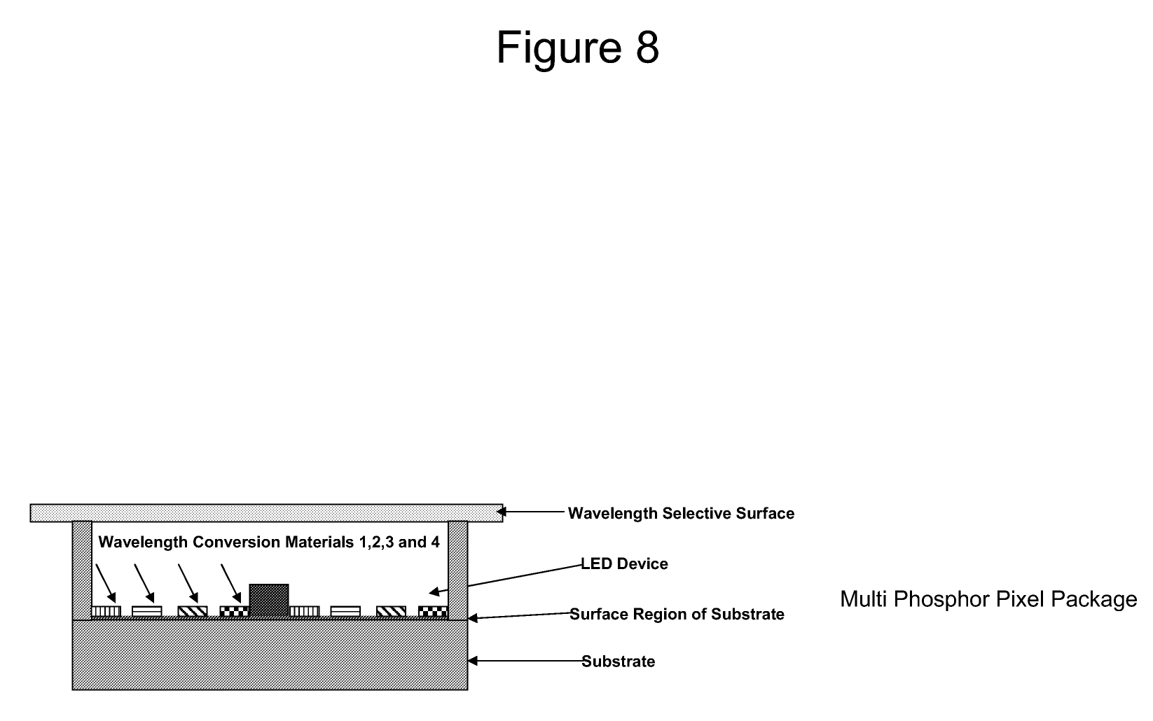

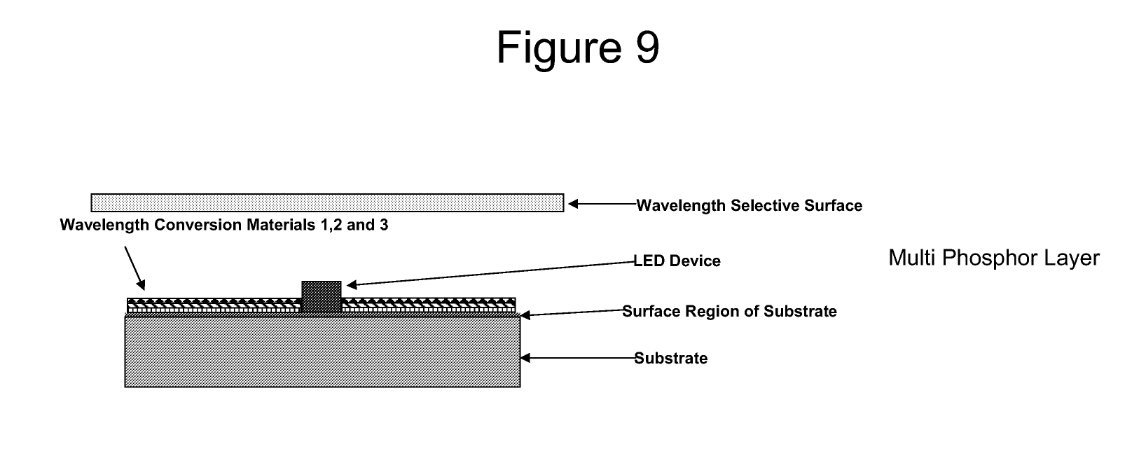

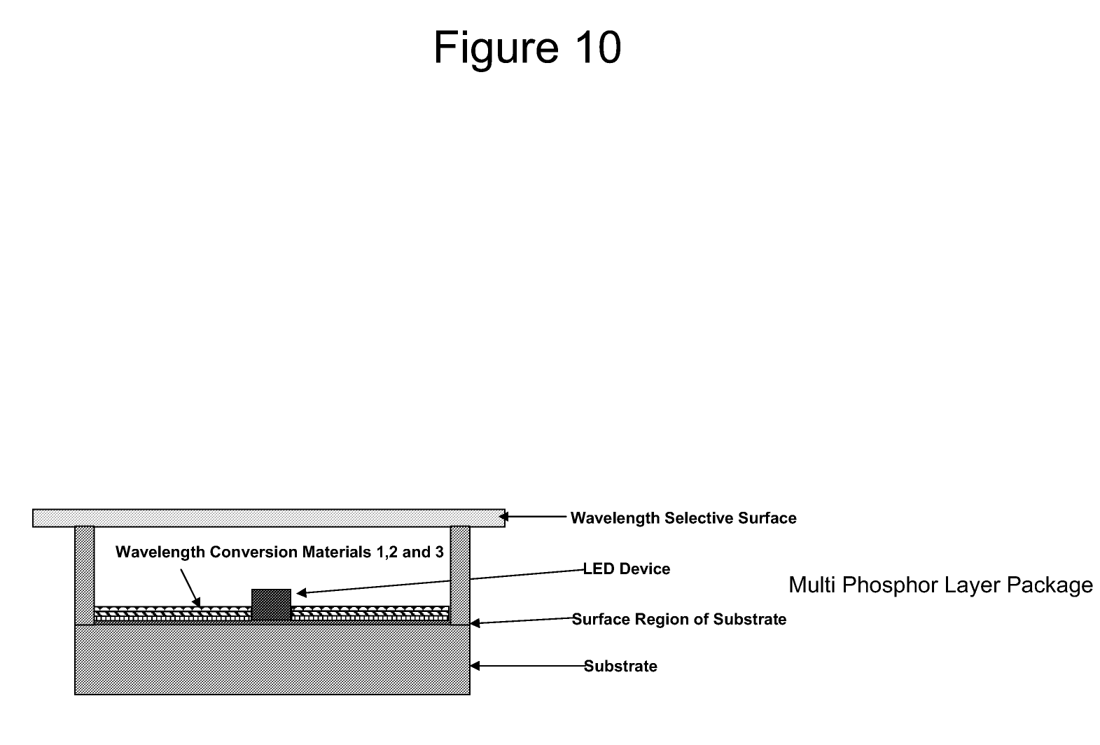

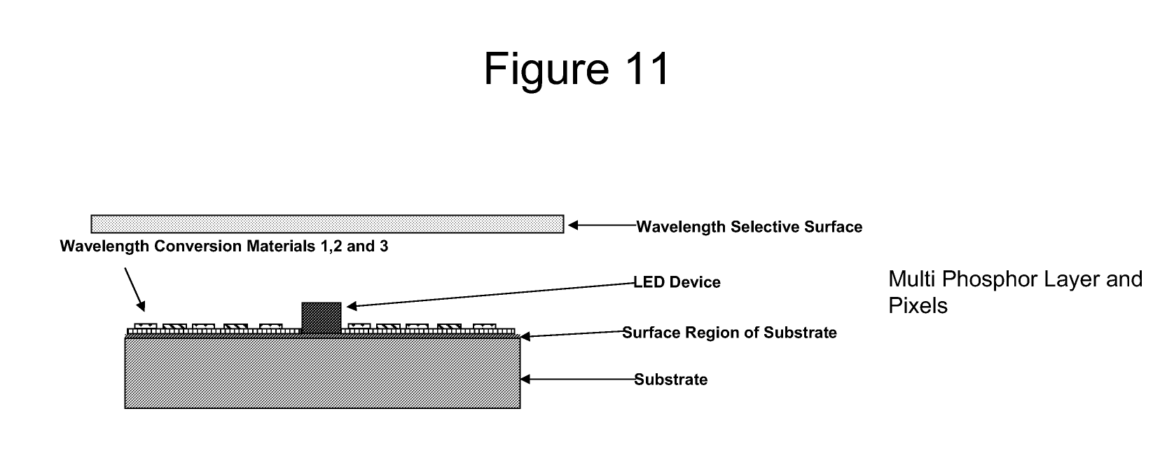

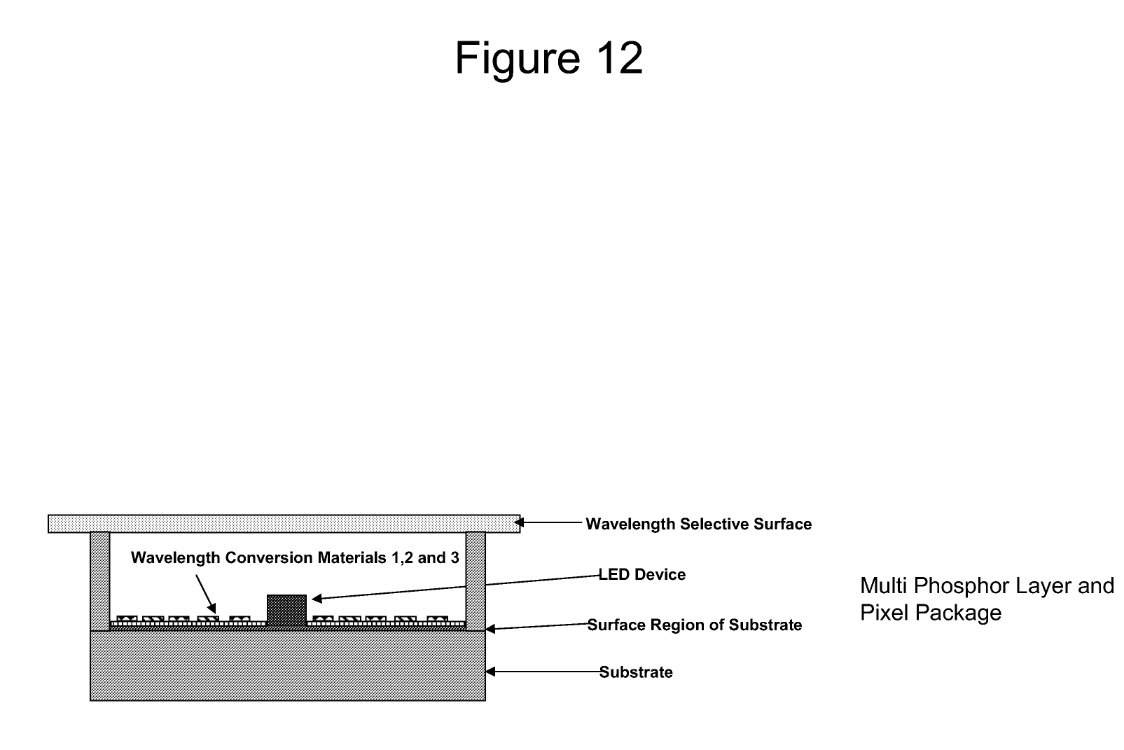

FIGS. 2 through 12 are simplified diagrams of alternative packaged light emitting devices using one or more reflection mode configurations according to embodiments of the present invention. In a specific embodiment, the enclosure comprises an interior region and an exterior region with a volume defined within the interior region. The volume is open and filled with an inert gas or air to provide an optical path between the LED device or devices and the surface region of the enclosure. In a preferred embodiment, the optical path includes a path from the wavelength selective material to the wavelength conversion material and back through the wavelength conversion material. In a specific embodiment, the enclosure also has a thickness and fits around a base region of the substrate.

In a specific embodiment, the plurality of entities is suspended in a suitable medium. An example of such a medium can be a silicone, glass, spin on glass, plastic, polymer, which is doped, metal, or semiconductor material, including layered materials, and/or composites, among others. Depending upon the embodiment, the medium including polymers begins as a fluidic state, which fills an interior region of the enclosure. In a specific embodiment, the medium fills and can seal the LED device or devices. The medium is then cured and fills in a substantially stable state according to a specific embodiment. The medium is preferably optically transparent or can also be selectively transparent and/or translucent according to a specific embodiment. In addition, the medium, once cured, is substantially inert according to a specific embodiment. In a preferred embodiment, the medium has a low absorption capability to allow a substantial portion of the electromagnetic radiation generated by the LED device to traverse through the medium and be outputted through the enclosure at one or more second wavelengths. In other embodiments, the medium can be doped or treated to selectively filter, disperse, or influence one or more selected wavelengths of light. As an example, the medium can be treated with metals, metal oxides, dielectrics, or semiconductor materials, and/or combinations of these materials, and the like.

Although the above has been described in terms of an embodiment of a specific package, there can be many variations, alternatives, and modifications. As an example, the LED device can be configured in a variety of packages such as cylindrical, surface mount, power, lamp, flip-chip, star, array, strip, or geometries that rely on lenses (silicone, glass) or sub-mounts (ceramic, silicon, metal, composite). Alternatively, the package can be any variations of these packages.

In other embodiments, the packaged device can include one or more other types of optical and/or electronic devices. As an example, the optical devices can be OLED, a laser, a nanoparticle optical device, and others. In other embodiments, the electronic device can include an integrated circuit, a sensor, a micro-machined electronic mechanical system, or any combination of these.

In a specific embodiment, the packaged device can be coupled to a rectifier to convert alternating current power to direct current, which is suitable for the packaged device. The rectifier can be coupled to a suitable base, such as an Edison screw such as E27 or E14, bipin base such as MR16 or GU5.3, or a bayonet mount such as GU10, or others. In other embodiments, the rectifier can be spatially separated from the packaged device.

Additionally, the present packaged device can be provided in a variety of applications. In a preferred embodiment, the application is general lighting, which includes buildings for offices, housing, outdoor lighting, stadium lighting, and others. Alternatively, the applications can be for display, such as those used for computing applications, televisions, flat panels, micro-displays, and others. Still further, the applications can include automotive, gaming, and others.

In a specific embodiment, the present devices are configured to achieve spatial uniformity. That is, diffusers can be added to the encapsulant to achieve spatial uniformity. Depending upon the embodiment, the diffusers can include TiO₂, CaF₂, SiO₂, CaCO₃, BaSO₄, and others, which are optically transparent and have a different index than the encapsulant causing the light to reflect, refract, and scatter to make the far field pattern more uniform.

As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k l) plane wherein h=k=0, and l is non-zero), non-polar GaN substrates (i.e., substrate material where the largest area surface is oriented at an angle ranging from about 80-100 degrees from the polar orientation described above towards an (h k l) plane wherein l=0, and at least one of h and k is non-zero) or semi-polar GaN substrates (i.e., substrate material where the largest area surface is oriented at an angle ranging from about +0.1 to 80 degrees or 110-179.9 degrees from the polar orientation described above towards an (h k l) plane wherein l=0, and at least one of h and k is non-zero).

Wavelength conversion materials can be ceramic or semiconductor particle phosphors, ceramic or semiconductor plate phosphors, organic or inorganic downconverters, upconverters (anti-stokes), nanoparticles and other materials which provide wavelength conversion. Some examples are listed below:
(Sr,Ca)10(PO4)6*B2O3:Eu2+ (wherein 0<n̂1)
(Ba,Sr,Ca)5(PO4)3(Cl,F,Br,OH):Eu2+,Mn2+
(Ba,Sr,Ca)BPO5:Eu2+,Mn2+
Sr2Si3O8*2SrCl2:Eu2+
(Ca,Sr,Ba)3MgSi2O8:Eu2+, Mn2+
BaAl8O13:Eu2+
2SrO*0.84P2O5*0.16B2O3:Eu2+
(Ba,Sr,Ca)MgAl10O17:Eu2+,Mn2+
K2SiF6:Mn4+
(Ba,Sr,Ca)Al2O4:Eu2+
(Y,Gd,Lu,Sc,La)BO3:Ce3+,Tb3+
(Ba,Sr,Ca)2(Mg,Zn)Si2O7:Eu2+
(Mg,Ca,Sr,Ba,Zn)2Si1_xO4_{—}2x:Eu2+(wherein 0<x=0.2)
(Sr,Ca,Ba)(Al,Ga,m)2S4:Eu2+
(Lu,Sc,Y,Tb)2_u_vCevCa1+uLiwMg2_wPw(Si,Ge)3_w012_u/2 where —O.SSû1; 0<v£Q.1; and OSŵO.2
(Ca,Sr)8(Mg,Zn)(SiO4)4Cl2:Eu2+,Mn2+
Na2Gd2B2O7:Ce3+,Tb3+
(Sr,Ca,Ba,Mg,Zn)2P2O7:Eu2+,Mn2+
(Gd,Y,Lu,La)2O3:Eu3+,Bi3+
(Gd,Y,Lu,La)2O2S:Eu3+,Bi3+
(Gd,Y,Lu,La)VO4:Eu3+,Bi3+
(Ca,Sr)S:Eu2+,Ce3+
(Y,Gd,Tb,La,Sm,Pr,Lu)3(Sc,Al,Ga)5_nO12_{—}3/2n:Ce3+ (wherein 0̂0̂0.5)
ZnS:Cu+,Cl˜
ZnS:Cu+,Al3+
ZnS:Ag+,Al3+
SrY2S4:Eu2+
CaLa2S4:Ce3+
(Ba,Sr,Ca)MgP2O7:Eu2+,Mn2+
(Y,Lu)2WO6:Eu3+,Mo6+
CaWO4
(Y,Gd,La)2O2S:Eu3+
(Y,Gd,La)2O3:Eu3+
(Ca,Mg)xSyO:Ce
(Ba,Sr,Ca)nSinNn:Eu2+ (wherein 2n+4=3n)
Ca3(SiO4)Cl2:Eu2+
ZnS:Ag+,Cl˜
(Y,Lu,Gd)2_nCanSi4N6+nC1_n:Ce3+, (wherein OSn̂O.5)
(Lu,Ca,Li,Mg,Y)alpha-SiAlON doped with Eu2+ and/or Ce3+
(Ca,Sr,Ba)SiO2N2:Eu2+,Ce3+
(Sr,Ca)AlSiN3:Eu2+
CaAlSi(ON)3:Eu2+
Sr10(PO4)6Cl2:Eu2+
(BaSi)O12N2:Eu2+
SrSi2(O,Cl)2N2:Eu2+
(Ba,Sr)Si2(O,Cl)2N2:Eu2+
LiM2O8:Eu3+ where M=(W or Mo)
   For purposes of the application, it is understood that when a phosphor has two or more dopant ions (i.e. those ions following the colon in the above phosphors), this is to mean that the phosphor has at least one (but not necessarily all) of those dopant ions within the material. That is, as understood by those skilled in the art, this type of notation means that the phosphor can include any or all of those specified ions as dopants in the formulation.

The above has been generally described in terms of one or more entities that may be one or more phosphor materials or phosphor like materials, but it would be recognized that other “energy-converting luminescent materials,” which may include one or more phosphors, semiconductors, semiconductor nanoparticles (“quantum dots”), organic luminescent materials, and the like, and combinations of them, can also be used. In one or more preferred embodiments, the energy converting luminescent materials can generally be one or more wavelength converting material and/or materials or thicknesses of them. Furthermore, the above has been generally described in electromagnetic radiation that directly emits and interacts with the wavelength conversion materials, but it would be recognized that the electromagnetic radiation can be reflected and then interacts with the wavelength conversion materials or a combination of reflection and direct incident radiation. In other embodiments, the present specification describes one or more specific gallium and nitrogen containing surface orientations, but it would be recognized that any one of a plurality of family of plane orientations can be used. Therefore, the above description and illustrations should not be taken as limiting the scope of the present invention which is defined by the appended claims.

1. An optical device comprising:
a substrate member having a surface region;
at least one LED configured overlying one or more portions of the surface region;
at least one exposed portion of the surface region;
a wavelength conversion material disposed overlying the at least one exposed portion; and
a wavelength selective surface configured to block substantially direct emission of the at least one LED and configured to transmit at least one selected wavelength of reflected emission caused by an interaction with the wavelength conversion material.

2. The device of claim 1 wherein the wavelength selective surface comprises a transparent material.

3. The device of claim 1 wherein the wavelength selective surface comprises an outer portion of a package housing the at least one LED.

4. The device of claim 1 wherein the surface region is made of a metal material, a semiconductor material, a dielectric material, or combinations.

5. The device of claim 1 wherein the at least one selected wavelength is provided by a filter.

6. The device of claim 1 wherein the surface region is substantially planar.

7. (canceled)

8. The device of claim 1 wherein the wavelength conversion material comprises a phosphor.

9. The device of claim 1 wherein the substrate member and wavelength selective surface are configured as a package.

10-15. (canceled)

16. An optical device comprising:
a substrate member comprising a surface region;
at least one LED configured overlying one or more first portions of the surface region, the at least one LED having LED surface regions;
at least one second portion of the surface region;
a wavelength conversion material disposed overlying the second portions and configured to expose the LED surface regions.

17. The optical device of claim 16 wherein the wavelength conversion material has a density, a thickness, a surface region, the surface region is uneven with the LED surface regions.

18. (canceled)

19. The optical device of claim 16 wherein the LED surface regions is a substantial portion of an entirety of a total surface region of the surface region.

20-29. (canceled)

30. An optical device comprising:
a substrate member comprising a surface region;
at least one LED configured overlying at least one portion of the surface region, the at least one LED having LED surface regions and characterized by a first height from a reference region;
a wavelength conversion material configured to have an upper surface having a second height from the reference region; and
whereupon the second height is about less than the first height.

31. The device of claim 30 wherein the wavelength conversion material comprises a thickness, the wavelength conversion material being with about three hundred microns of a thermal sink.

32. The device of claim 31 wherein the thermal sink comprises a surface region.

33-37. (canceled)

38. The device of claim 30 wherein the wavelength conversion material is characterized by an average particle-to-particle distance of about less than about 3 times the average particle size of the wavelength conversion material.

39. The device of claim 30 wherein the wavelength conversion material is characterized by an average particle-to-particle distance of about less than about 5 times the average particle size of the wavelength conversion material.

40-41. (canceled)

42. The device of claim 30 further comprising an optically transparent member.

43-45. (canceled)

46. The device of claim 30 wherein the wavelength conversion material comprises one or more entities comprising a phosphor or phosphor blend selected from one or more of (Y, Gd, Tb, Sc, Lu, La)₃(Al, Ga, In)₅O₁₂:Ce³⁺, SrGa₂S₄:Eu²⁺, SrS:Eu²⁺, and colloidal quantum dot thin films comprising CdTe, ZnS, ZnSe, ZnTe, CdSe, or CdTe.

47. The device of claim 30 wherein the wavelength conversion material further comprising a phosphor capable of emitting substantially red light, wherein the phosphor is selected from one or more of the group consisting of (Gd,Y,Lu,La)₂O₃:Eu³⁺, Bi³⁺; (Gd,Y,Lu,La)₂O₂S:Eu³⁺, Bi³⁺; (Gd,Y,Lu,La)VO₄:Eu³⁺, Bi³⁺; Y₂(O,S)₃: Eu³⁺; Ca₁₋ₓMo_{1-y}Si_{y}O₄, where 0.05≦x≦0.5, 0≦y≦0.1; (Li,Na,K)₅Eu(W,Mo)O₄; (Ca,Sr)S:Eu²⁺; SrY₂S₄:Eu²⁺; CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgₓP₂O₇:Eu²⁺, Mn²⁺; (Y,Lu)₂WO₆:Eu³⁺, Mo⁶⁺; (Ba,Sr,Ca)₃MgₓSi₂O₈:Eu²⁺, Mn²⁺, wherein 0.1<x≦2; (RE_{1-y}Ce_{y})Mg₂₋ₓLiₓSi₃₋ₓPxO₁₂, where RE is at least one of Sc, Lu, Gd, Y, and Tb, 0.0001<x<0.1 and 0.001<y<0.1; (Y, Gd, Lu, La)₂₋ₓEuₓW_{1-y}Mo_{y}O₆,where 0.5≦x.≦1.0, 0.01≦y≦1.0; (SrCa)₁₋ₓEuₓSi₅N₈, where 0.01≦x≦0.3; SrZnO₂:Sm⁺³; MₘOₙX, wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

48-52. (canceled)
